(19) United States
(12) Patent Application Publication
(10) Pub. No.: US 2015/0207071 A1
(43) Pub. Date: Jul. 23, 2015

(54) RESISTIVE RANDOM ACCESS MEMORY DEVICE AND MANUFACTURING METHOD OF RESISTIVE ELEMENT FILM

(71) Applicant: Kabushiki Kaisha Toshiba, Minato-ku (JP)

(72) Inventors: Hiroyuki ODE, Yokkaichi-shi (JP); Takeshi Yamaguchi, Yokkaichi-shi (JP); Shigeki Kobayashi, Kuwana-shi (JP); Masaki Yamato, Yokkaichi-shi (JP); Yoshinori Nakakubo, Yokkaichi-shi (JP)

(73) Assignee: Kabushiki Kaisha Toshiba, Minato-ku (JP)

(21) Appl. No.: 14/299,263

(22) Filed: Jun. 9, 2014

Related U.S. Application Data
(60) Provisional application No. 61/930,305, filed on Jan. 22, 2014.

(51) Int. Cl. H01L 45/00; H01L 27/24

(52) U.S. Cl. CPC H01L 45/1616; H01L 45/1253; H01L 27/2409

(57) ABSTRACT

In accordance with an embodiment, a manufacturing method of a resistive element film includes sequentially repeating, a desired number of times, first and second film formation cycles. In the first film formation cycle, an insulating film is formed up to a continuous layer by an ALD film formation method under a first condition. In the second film formation cycle a metal film is formed on the insulating film up to a continuous layer by the ALD film formation method under a second condition.

### CROSS REFERENCE TO RELATED APPLICATIONS

This application is based upon and claims the benefit of U.S. provisional Application No. 61/930,305, filed on Jan. 22, 2014, the entire contents of which are incorporated herein by reference.

### FIELD

Embodiments described herein relate generally to a resistive random access memory device and a manufacturing method of resistive random access memory device having resistive element film.

### BACKGROUND

In association with a resistive random access memory device (hereinafter briefly referred to as a “ReRAM”), a resistive element for overcurrent suppression may be connected to a resistance-changing film. Here, when the resistance value of this resistive element changes nonlinearly relative to a voltage, it may be possible to shift from a target resistance value during each operation (read, set, or reset) of the ReRAM.

### BRIEF DESCRIPTION OF THE DRAWINGS

In the accompanying drawings:

FIG. 1 is an example of a sectional view showing a general configuration of a resistive element according to one embodiment;

FIG. 2A to FIG. 2D show examples of graphs representing the relation between current and voltage of a resistive element film shown in FIG. 1;

FIG. 3A to FIG. 3C are explanatory diagrams showing an example of a manufacturing method of the resistive element film shown in FIG. 1;

FIG. 4 is a block diagram showing an example of a general configuration of a semiconductor memory device according to Embodiment 1;

FIG. 5 shows an example of a perspective view of Example 1 of a memory cell array included in the semiconductor memory device shown in FIG. 4;

FIGS. 6A and 6B show examples of perspective views of one memory cell viewed in an arrow direction through the line II-II in FIG. 5; and

FIG. 7 shows an example of a perspective view of Example 2 of the memory cell array included in the semiconductor memory device shown in FIG. 4.

### DETAILED DESCRIPTION

In accordance with an embodiment, a manufacturing method of a resistive element film includes sequentially repeating, a desired number of times, first and second film formation cycles. In the first film formation cycle, an insulating film is formed up to a continuous layer by an ALD film formation method under a first condition. In the second film formation cycle a metal film is formed on the insulating film up to a continuous layer by the ALD film formation method under a second condition.

Embodiments will now be explained with reference to the accompanying drawings. Like components are provided with like reference signs throughout the drawings and repeated descriptions thereof are appropriately omitted. It is to be noted that the drawings described below are made to facilitate the explanation, sizes and dimensions may thus be different from the actual sizes and dimensions in each of the drawings or between the drawings.

(1) Resistive Element Film

(a) Device Structure

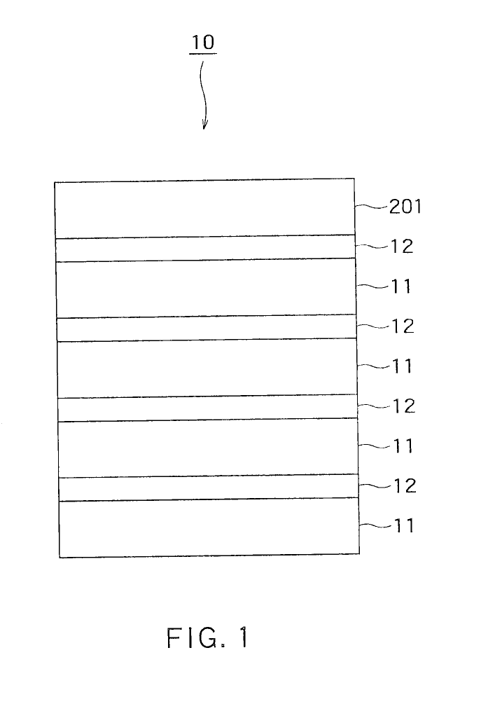

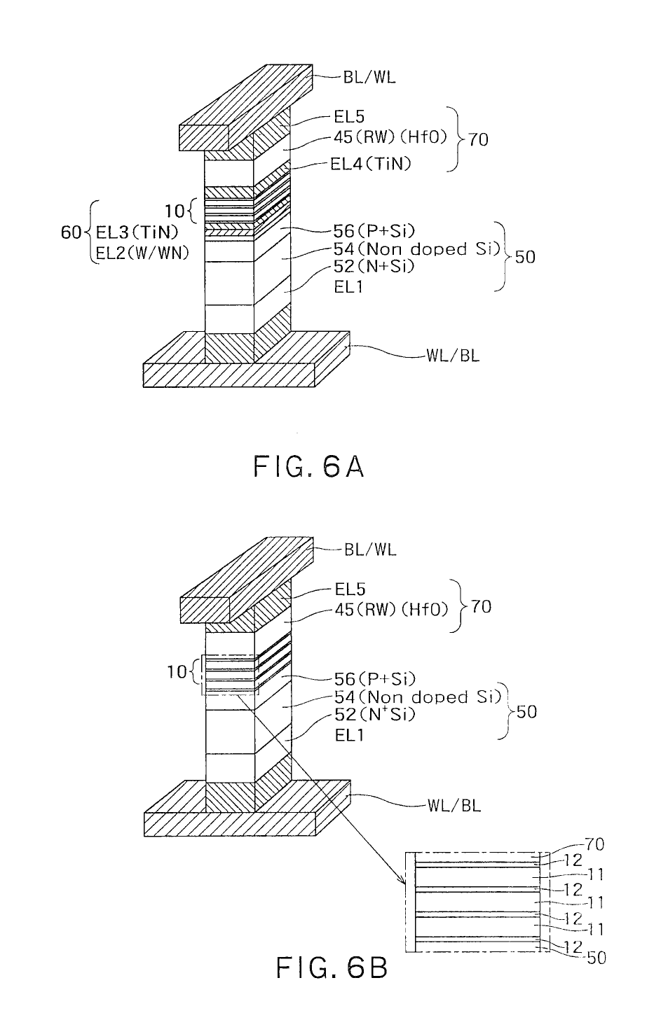

FIG. 1 is a sectional view showing a general configuration of a resistive element according to one embodiment. In the case described here, a laminate resistive element film is used as the resistive element. A resistive element film 10 shown in FIG. 1 includes a stack body and an insulating film 201 on this stack body. In the stack body insulating films 11 and metallic films 12 that are independent of each other are alternately and repetitively stacked in this order. Here, the metallic film 12 is a film containing a metal, and may include a nitride or oxide. Here, the stack body may be disposed on, for example, electrodes EL2 and EL3 in FIG. 6A. Although the insulating films 11 and the metallic films 12 are repetitively stacked four times in the example shown in FIG. 1, the number of repetitions is not at all limited thereto, and any number of repetitions can be selected in accordance with product specifications such as the resistivity of the whole resistive element film.

The metallic film 12 is a tantalum nitride film with crystalline in the present embodiment, but is not limited thereto. For example, it is also possible to use films of titanium nitride (TiN), molybdenum nitride (MoN), nickel nitride (NiN), niobium nitride (NbN), and vanadium nitride (VN). The insulating film 11 is an amorphous silicon nitride (SiN) film in the present embodiment, but is not limited thereto. For example, the insulating film 11 may be an aluminum nitride (AlN) film.

The thickness of the insulating film 11 between the metallic films 12 can be adjusted to a range of 1 nm to 5 nm, preferably a range of 1.5 nm to 3 nm in consideration of the relation (linearity) between current and voltage and the resistance value of the whole resistive element film 10, as will be described later.

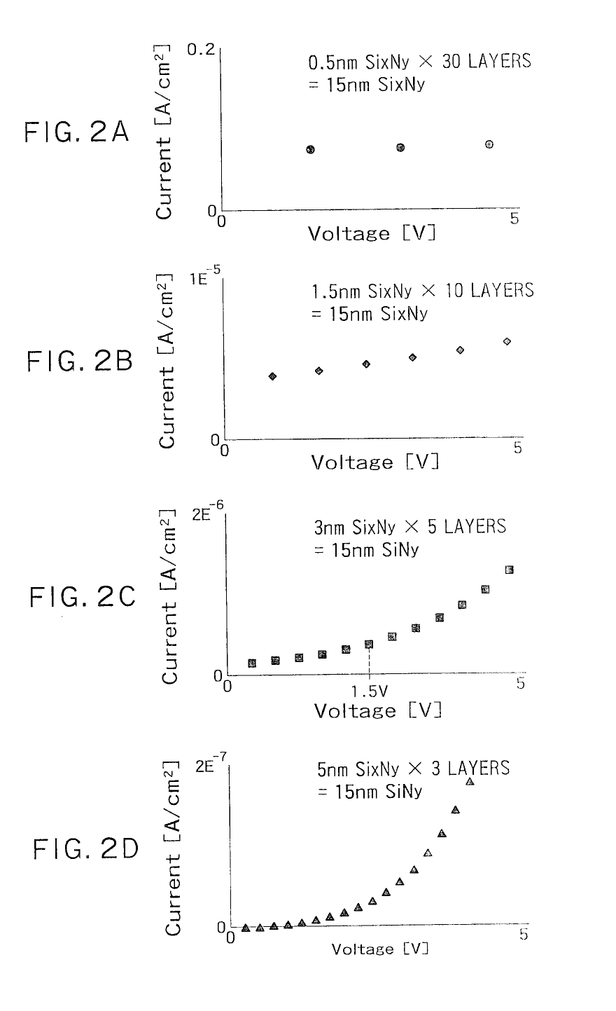

FIG. 2A to FIG. 2D show examples of graphs obtained by simulations of the current-voltage relation using the thickness of the insulating film 11 as a parameter. In FIG. 2A to FIG. 2D, the total thickness of the insulating films 11 is calculated at 15 nm. Specifically, FIG. 2A shows the relation between current and voltage when the thickness of the insulating film 11 is 0.5 nm (×30 layers=15 nm); FIG. 2B shows the relation between current and voltage when the thickness of the insulating film 11 is 1.5 nm (×10 layers=15 nm); FIG. 2C shows the relation between current and voltage when the thickness of the insulating film 11 is 3 nm (×5 layers=15 nm); and FIG. 2D shows the relation between current and voltage when the thickness of the insulating film 11 is 5 nm (×3 layers=15 nm). Here, lines connecting plots in FIG. 2A to FIG. 2D are IV curves.

The linearity of the IV curve hardly depends on the thickness of the metallic film 12.

As obvious from the IV curves respectively shown in FIG. 2A to FIG. 2D, the linearity of the IV curve is better when the thickness of the insulating film 11 between the metallic films 12 is smaller, but the resistance value is lower.

As obvious from the IV curves respectively shown in FIG. 2A to FIG. 2D, the resistance value is higher when the thickness of the insulating film 11 is greater, so that the dielectric breakdown voltage is higher, but the linearity of the IV curve deteriorates.

Depending on the application aspect of the resistive element film 10, the deterioration of the linearity of the IV curve may affect element characteristics. As such an example, a case is described below in which the resistive element film 10 is used as a resistance between a memory cell of a ReRAM and a rectifier element.

When the insulating film 11 has a small thickness of 1.5 nm and 0.4 nm as shown in the IV curves in FIG. 2B and FIG. 2A, the resistance value of the resistive element film 10 is low, but satisfactory linearity is shown. This suggests that a leak current in a direct tunneling mode mainly prevails and that the contribution of a Schottky current resulting in nonlinearity is thus reduced.

Therefore, when the thickness of the insulating film 11 is 1.5 nm or less, forming process can be effectively carried out due to a small voltage drop (low resistance) in the resistive element. However, the resistance value of the resistive element film 10 may be too low to realize low current programming.

On the other hand, when the insulating film 11 has a large thickness of 3 nm and 5 nm as shown in the IV curves in FIG. 2C and FIG. 2D, the resistance value is high, but the linearity deteriorates.

Here, this tendency is noticeable in the IV curve shown in FIG. 2D in which the thickness of the insulating film 11 is 5 nm, whereas relatively satisfactory linearity can be maintained in a voltage region of 1.5 V or less in the IV curve shown in FIG. 2C in which the thickness of the insulating film 11 is 3 nm.

This suggests that a Schottky-induced leak current mainly prevails more than in the direct tunneling mode when the thickness of the insulating film 11 is more than 3 nm. Therefore, required resistance is obtained to realize low current programming, but the forming may be difficult.

Thus, when a resistive element having such a trade-off relation between the linearity of the IV curve and the resistance value of the insulating film is used as a current suppression element of the ReRAM, it is preferable that the linearity does not deteriorate while keeping a target resistance value.

Thus, in the resistive element film 10 according to the present embodiment, the insulating films 11 having satisfactory linearity and the metallic films 12 are repetitively formed more than once into a multilayer stack body structure, so that the resistance value of the resistive element film 10 can be higher while the linearity of the resistive element film 10 is maintained. More specifically, the thickness of the insulating film 11 between the metallic films 12 is adjusted to a range of 1 nm to 5 nm in the present embodiment, preferably a range of 1.5 nm to 3 nm. Consequently, the resistive element film 10 is expected to have a sufficient resistance value and also have satisfactory linearity.

The linearity and resistance value of the insulating him 11 can also be adjusted by the change of nitrogen concentration in the insulating film 11. That is, if the nitrogen concentration in the insulating film 11 is decreased, the resistivity decreases, but the linearity of the IV curve is improved. If the nitrogen concentration in the insulating film 11 is increased, the linearity of the IV curve deteriorates, but the resistivity increases.

Thus, the nitrogen concentration in the insulating film 11 can be adjusted so that the linearity of the resistive element film 10 does not deteriorate while keeping the target resistance value of the resistive element film 10. For example, in the case of the silicon nitride film according to the present embodiment, the nitrogen concentration in the insulating film 11 is adjusted to 1 to 60%. More specifically, the nitrogen concentration in the insulating film 11 is adjusted so that the relation 0<y≦4 is satisfied when the composition of silicon nitride is SiₓN_{y} (0<X, y) in which x=3.

In this way, at least any one of the thickness of the insulating film 11 between the metallic films 12 and the nitrogen concentration in the insulating film 11 is adjusted, se that a resistive element has linearity and the target resistance value.

In the present embodiment, the thickness of the metallic film 12 is 1 nm or more, and the thickness of the whole resistive element film 10 can be 5 nm or more.

In the resistive element film according to at least one embodiment described above, at least any one of the thickness of the insulating film and the nitrogen concentration is adjusted so that the linearity and resistance value of the whole resistive element film satisfy the targets. Therefore, it is possible to provide a resistive element film which has a target resistance value without the deterioration of the linearity of the IV curve.

The resistive element film 10 has only to have two or more insulating films 11, or two or more metallic films 12. That is, it can be said that the resistive element film 10 has a total of three or more layers of the insulating films 11 and the metallic films 12.

Application examples of the resistive element film according to the present embodiment can be cross-point type ReRAM. While this type ReRAM will be described later in detail as embodiments of semiconductor memory devices, it should be noted that the resistive element film according to the present embodiment is not limited to this device and is widely usable in devices in which the problem of the resistance value and the linearity is needed to be under control.

(b) Manufacturing Method

A manufacturing method of the resistive element film 10 shown in FIG. 1 is described.

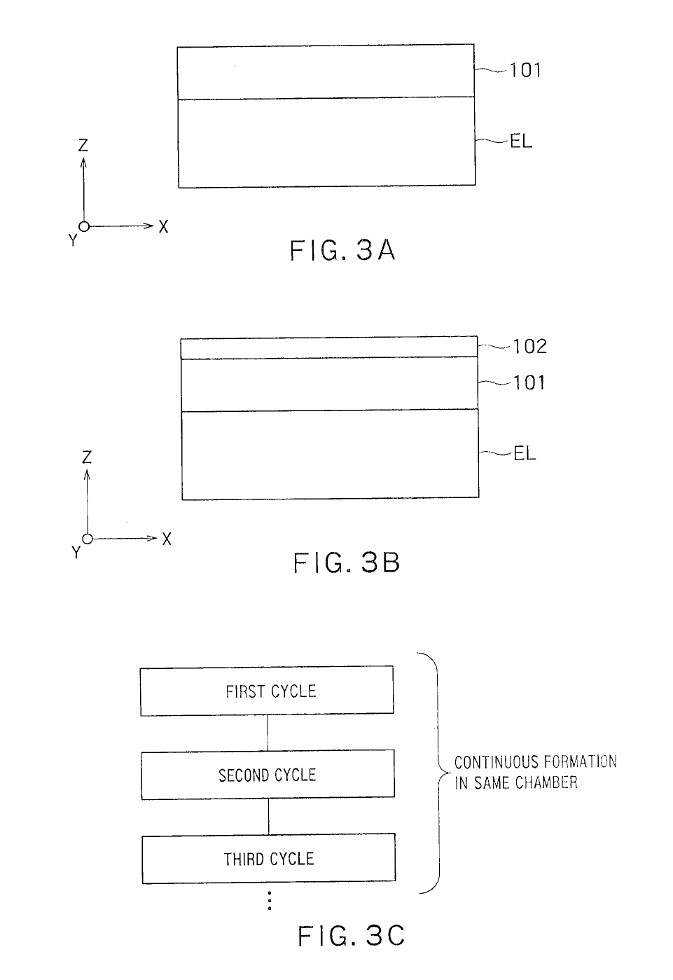

First, as shown in FIG. 3A, mono-silane (SiH₄) is used as a silicon (Si) material, and ammonia (NH₃) is used as a nitriding agent to form a silicon nitride (SiₓN_{y}) film 101 on a substrate such as an electrode EL (metallic film) by the ALD film formation method. This ALD film formation is conducted until a layer of silicon nitride (SiₓN_{y}) is formed on an XY plane continuously.

In the present embodiment, mono-silane (SiH₄) is used as a silicon (Si) material, and ammonia (NH₃) is used as a nitriding agent, and at least one of the thickness and the nitrogen concentration of the silicon nitride (SiₓN_{y}) film 101 is adjusted so that the linearity and resistance value of the whole resistive element film satisfy the targets. This corresponds to, for example, a first condition. The formation of the silicon nitride (SiₓN_{y}) film 101 by the ALD film formation method under the first condition corresponds to a first film formation cycle.

As shown in FIG. 3B, tertiary butylimido tris (diethylamino) tantalum (TBTDET) is then used as an organic tantalum (Ta) material, and ammonia (NH₃) is used as a nitriding agent, so that a tantalum nitride (TaN) film 102 is formed on the silicon nitride film 101 by the ALD film formation method until a layer of tantalum nitride (TaN) is formed on an XY plane continuously.

In the present embodiment, TBTDET is used as an organic tantalum (Ta) material, and ammonia (NH₃) is used as a nitriding agent. This corresponds to, for example, a second condition. The formation of the tantalum nitride (TaN) film 102 on the silicon nitride (SiₓN_{y}) film 101 corresponds to a second film formation cycle.

The above-mentioned film formation cycle of the silicon nitride (SiₓN_{y}) film 101 and the above-mentioned film formation cycle of the tantalum nitride (TaN) film 102 are sequentially repeated a predetermined number of times, and an uppermost silicon nitride (SiₓN_{y}) film 201 is formed in the end. As a result, the resistive element film 10 shown in FIG. 1 is manufactured. In this case, at least any one of the thickness and the nitrogen concentration of the silicon nitride (SiₓN_{y}) film 101 is adjusted in such a manner that the linearity and resistance value of the whole resistive element film satisfy the targets.

According to the manufacturing method of the resistive element film in at least one embodiment described above, the insulating films 11 and the metallic films 12 that are independent of each other are alternately and repetitively stacked, the stack body including the resistive element can thus be manufactured.

According to the manufacturing method of the resistive element film in at least one embodiment described above, at least one of the thickness and the nitrogen concentration of the silicon nitride (SiₓN_{y}) film 101 is adjusted and thus optimized in such a manner that the linearity of the IV curve of the resistive element film 10 and the resistance value of the resistive element film 10 satisfy the targets. Consequently, it is possible to manufacture a resistive element film having the target resistance value without the deterioration of the linearity of the IV curve.

As shown in FIG. 3C, the first cycle and the second cycle can be continuously performed in one chamber so that mono-silane and TBTDET are alternately supplied as source gas for the first cycle and the second cycle, respectively.

The film formation cycle to be first conducted may be the second cycle (TBTDET). The film formation cycle to be conducted in the end may be the second cycle (TBTDET).

(2) Semiconductor Memory Device

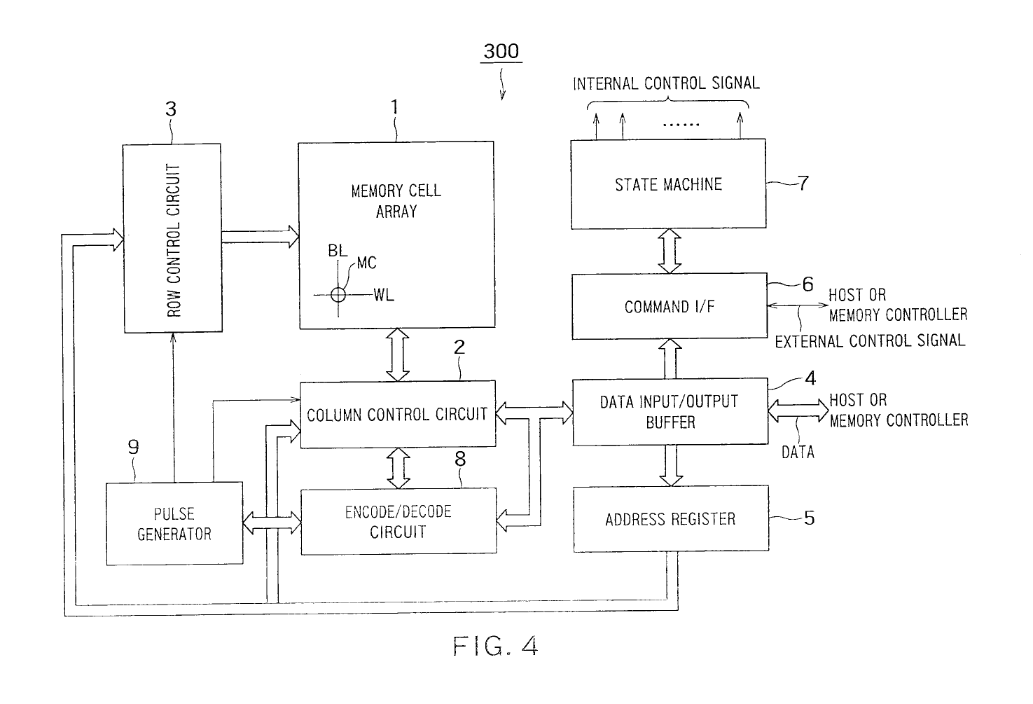

FIG. 4 is a block diagram showing a general configuration of a semiconductor memory device according to Embodiment 1.

A semiconductor memory device 300 according to the present example includes a memory cell array 1 which has a plurality of bit lines BL, a plurality of word lines WL intersecting with the bit lines BL, and a plurality of memory cells MC provided at the intersections of the bit lines BL and the Word lines WL. The memory cell MC is configured by a ReRAM in the present embodiment.

A column control circuit 2 which controls the bit: lines BL of the memory cell array 1 and which performs a write operation and a read operation for the memory cell MC is provided at a position adjacent to the memory cell array 1 in a bit line BL direction.

A row control circuit 3 which selects the word line WL of the memory cell array 1 and which applies a voltage necessary for the write operation and the read operation for the memory cell MC is provided at a position adjacent to the memory cell array 1 in a word line WL direction.

A data input/output buffer 4 is connected to an unshown external host via an I/O line, and receives write data, output read data, and receives address data and command data. The data input/output buffer 4 sends the received write data to the column control circuit 2, and receives the data read from the column control circuit 2 and then outputs the data to the outside. The address supplied to the data input/output buffer 4 from the outside is sent to the column control circuit 2 and the row control circuit 3 via an address register 5. The command supplied to the data input/output buffer 4 from the unshown host is sent to a command interface 6.

In response to an external control signal from the host or a memory controller, the command interface 6 judges whether the data inputted to the data input/output buffer 4 is write (late, a command, or an address. If the data is a command, the command interface 6 transfers the command to a state machine 7 as a receipt command signal.

The state machine 7 manages the whole semiconductor memory device 300, and performs the write operation, the read operation, and data input/output management in response to a command from the unshown host.

The data inputted to the data input/output buffer 4 from the host or the memory controller is transferred to an encode/decode circuit 8, and an output signal of the encode/decode circuit 8 is inputted to a pulse generator 9. The pulse generator 9 outputs a write pulse of a predetermined voltage and a predetermined timing in response to the input signal from the encode/decode circuit 8. The pulse generated in and outputted from the pulse generator 9 is transferred to a given wiring line selected by the column control circuit 2 the row control circuit 3.

(a) Cross-Point Type ReRAM

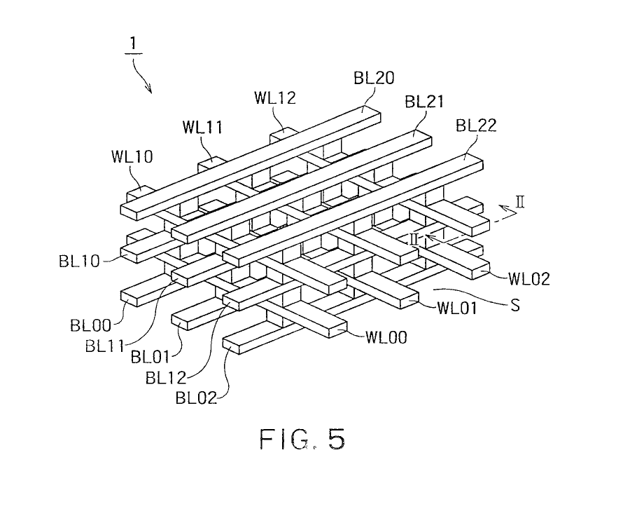

FIG. 5 shows an example of a perspective view of Example 1 of the memory cell array 1. FIG. 6A shows a perspective view of one memory cell viewed in an arrow direction through the line II-II in FIG. 5. In the present example, a plurality of bit lines BL0 to BL2 are provided in parallel on the main surface of a substrate S, a plurality of word lines WL0 to WL2 are provided in parallel across the bit lines, and the memory cells MC are arranged between the above lines at the intersections thereof.

The word lines WL0 to WL2 and the bit lines BL0 to BL2 are preferably made of heat-resistant materials having a low resistance values. For example, as such materials, tungsten (W), tungsten silicide (WSi), nickel silicide (NiSi), and cobalt silicide (CoSi) can be used. In the present example, the word lines WL0 to WL2 correspond to, for example, a first wiring line, and the bit lines BL0 to BL2 correspond to, for example, a second wiring line.

As shown in FIG. 6A, the memory cell MC in the semiconductor memory device 300 according to Example 1 is provided at the intersection of the lower word line WL (or the bit line BL) and the upper bit line BL (or the word line WL). The memory cell MC includes, for example, a diode 50 which is a PIN diode, a resistive element portion 60, and a memory element portion 70. The diode 50, the resistive element portion 60, and the memory element portion 70 are stacked and formed in a columnar shape in a direction perpendicular to the main surface of the substrate S from the lower layer to the upper layer.

The diode 50 has a lower electrode EL1, an n-type semiconductor (N⁺ Si) 52, an intrinsic semiconductor (nondoped Si) 54, and a p-type semiconductor (P⁺ Si) 56 are formed in this order from the lower layer to the upper layer. The diode 50 functions as a rectifier element. In the present example, the lower electrode EL1 corresponds to, for example, a first electrode.

The resistive element portion 60 is a stack body in which an electrode EL2, an electrode EL3, and the resistive element film 10 are sequentially arranged from the lower layer to the upper layer. For example, a stacked electrode of W/WN can be used as the electrode EL2, and TiN can be used as the electrode EL3. The electrode EL2 and the electrode EL3 may be integrated with each other. In the present example, the electrode EL2 and the electrode EL3 correspond to, for example, a second electrode.

The memory element portion 70has an electrode EL4, a variable resistance layer 45, and an upper electrode EL5 are sequentially formed from the lower layer to the upper layer. For example, TiN can be used as the electrode EL4. In the present example, the upper electrode EL5 corresponds to, for example, a third electrode.

The variable resistance layer 45 is made of, for example, a metal oxide. More specifically, the variable resistance layer 45 is made of, for example, hafnium oxide (HfOₓ), aluminum oxide (Al₂Oₓ), titanium oxide (TiOₓ), nickel oxide (NiOₓ), tungsten oxide (WOₓ), or tantalum oxide (Ta₂Oₓ), and these material are rather oxygen-depleted than in a stoichiometric state.

For the variable resistance layer 45, it is possible to use polycrystalline or amorphous silicon (Si), or silicon oxide (SiO), silicon oxynitride (SiON), silicon nitride (SiN), germanium (Ge), silicon germanium (SiGe), gallium arsenide (GaAs), indium phosphide (InP), gallium phosphide (GaP), gallium indium arsenide-phosphide (GaInAsP), gallium nitride (GaN), silicon carbide (SiC), hafnium silicide (HfSiO), hafnium oxide (HfO), or aluminum oxide (AlO) and so on. It is also possible to use stacked films of the above-mentioned materials for the resistance-changing materials. In the case of these resistance-changing materials, it is possible to arrange, as the electrode EL4 or the electrode EL5, electrodes made of, for example, silver (Ag), gold (Au), titanium (Ti), nickel (Ni), cobalt (Co), aluminum (Al), iron (Fe), chromium (Cr), copper (Cu), tungsten (W), hafnium (Hf), tantalum (Ta), platinum (Pt), ruthenium (Ru), zirconium (Zr), or indium (Ir), or a nitride or carbide thereof. As the electrode EL4 or the electrode EL5, it is also possible to use a material in which the above-mentioned materials are added to polycrystalline silicon.

The memory cell MC is preferably thinner for fabrication. Therefore, the thickness of the resistive element film 10 is preferably about 20 nm.

The resistive element film 10 according to the present embodiment is manufactured by the above-described manufacturing method (see FIG. 3A and FIG. 3B), and includes a stack body in which the insulating films 11 and the metallic films 12 that are independent of each other are alternately arranged. Thus, at least any one of the thickness and the nitrogen concentration of the insulating film 11 is adjusted in such a manner that the linearity of the IV curve of the whole resistive element film 10 and the resistance value of the whole resistive element film 10 satisfy the targets. Therefore, the resistive element film 10 functions as a current suppression element having the target resistivity without the deterioration of the linearity of the IV curve. As a result, according to the present embodiment, a cross-point ReRAM has appropriately effective resistance applicable at all voltages for the ReRAM operation and has considerably improved switching performance; for example, it is possible to reduce a switching voltage or a switching current.

Here, the lowermost layer of the stack body film 10 may be either the insulating film 11 or the metallic film 12. The uppermost layer of the stack body film 10 may also be either the insulating film 11 or the metallic film 12.

As shown in FIG. 6B, the electrodes EL2, EL3, and EL4 can be omitted. When the electrodes EL2 and EL3 are omitted, the stack body film 10 and the diode 50 are in direct contact with each other. In this case, the film of the stack body film 10 which is in contact with the diode 50 is preferably the metallic film 12.

When the electrode EL4 is omitted, the stack body film 10 and the memory element portion 70 are in direct contact with each other. In this case, the film of the stack body film 10 which is in contact with the memory element portion 70 is preferably the metallic film 12.

(b) Other Three-Dimensional Structure ReRAM

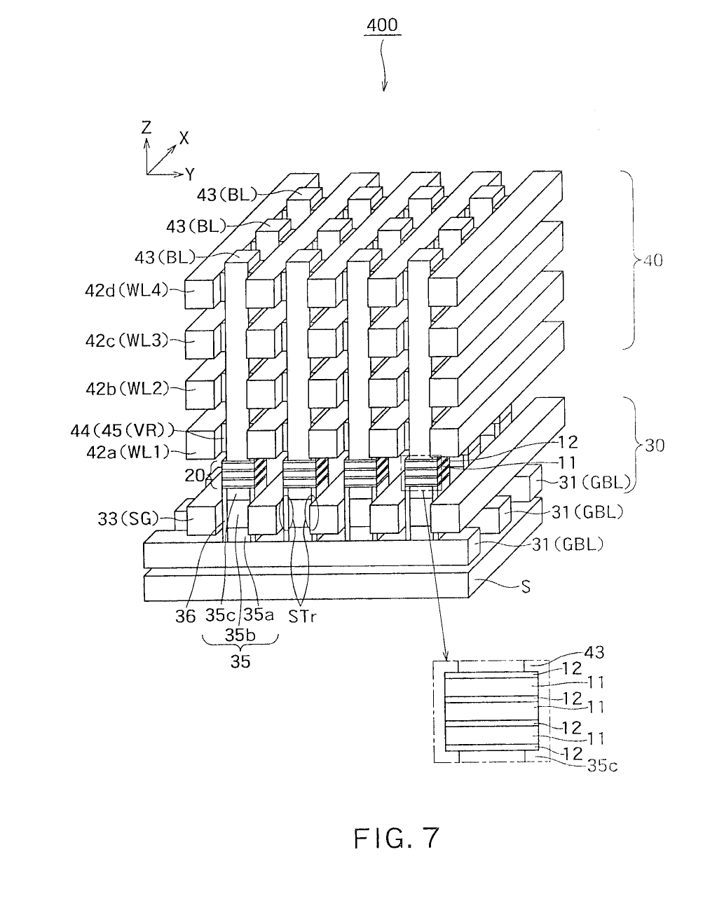

FIG. 7 shows an example of a perspective view of Example 2 of the memory cell array included in the semiconductor memory device shown in FIG. 4. As shown in FIG. 7, a semiconductor memory device 400 according to the present example has a select transistor layer 30, a resistive element film 20, and a memory layer 40 which are sequentially stacked on a substrate S. The select transistor layer 30 functions as a select transistor STr, and the memory layer functions as a memory cell MC.

The select transistor layer 30 has electric conducting layers 31 and electric conducting layers 33 that are stacked via interlayer insulating layers (not shown) in a Z-direction perpendicular to the substrate S. The electric conducting layers 31 function as global bit lines GBL, and the electric conducting layers 33 function as select gate lines SG and gates of select transistors STr. In the present example, the electric conducting layers 31 correspond to, for example, a third electric conducting layer.

The electric conducting layers 31 are arranged with a predetermined pitch in an X-direction parallel to the substrate S, and extend in a Y-direction. Part of the side surface of the electric conducting layer 31 and the upper surface thereof are covered with the interlayer insulating layers (not shown). The electric conducting layers 33 are arranged with a predetermined pitch in the Y-direction, and extend in the X-direction. Part of the side surface of the electric conducting layer 33 and the upper surface thereof are covered with the interlayer insulating layers (not shown). The electric conducting layers 31 and 33 are made of, for example, polysilicon. The unshown interlayer insulating layers are made of, for example, silicon oxide (SiO₂).

As shown in FIG. 7, the select transistor layer 30 also has a columnar semiconductor layer 35 and a gate insulating film 36. The semiconductor layer 35 functions as a body (channel) of the select transistor STr, and the gate insulating film 36 functions as a gate insulating film of the select transistor STr.

The semiconductor layer 35 is arranged in matrix form in the X- and Y-directions, and extends in a columnar shape in the Z-direction. The semiconductor layer 35 is in contact with the upper surface of the electric conducting layer 31, and is in contact with the side surface at a Y-direction end of the electric conducting layer 33 via the gate insulating film 36. The semiconductor layer 35 has, for example, an N⁺-type semiconductor layer 35a, a P⁺-type semiconductor layer 35b, and an N⁺-type semiconductor layer 35c that are stacked. The N⁺-type semiconductor layers 35a and 35c are made of polysilicon doped with an N⁺-type impurity. The P⁺-type semiconductor layer 35b is made of polysilicon doped with a P⁺-type impurity. The gate insulating film 36 is made of, for example, silicon oxide (SiO₂).

As shown in FIG. 7, the memory layer 40 has electric conducting layers 42a to 42d stacked in the Z-direction via interlayer insulating layers (not shown). The electric conducting layers 42a to 42d extend in the X-direction, and function as word lines WL1 to WL4. In the present example, the electric conducting layers 42a to 42d correspond to, for example, a second electric conducting layer.

The electric conducting layers 42a to 42d are made of, for example, titanium nitride (TiN). The unshown interlayer insulating layers are made of, for example, silicon oxide (SiO₂).

As shown in FIG. 7, the memory layer 40 also has an electric conducting layer 43 and a sidewall layer 44. The electric conducting layer 43 is arranged in matrix form in the X- and Y-directions, is in contact with the upper surface of the resistive element film 20, and extends in a columnar shape in the Z-direction together with the resistive element film 20. The electric conducting layer 43 functions as a bit line BL. In the present example, the electric conducting layer 43 corresponds to, for example, a first electric conducting layer, and the X-direction and the Z-direction correspond to, for example, a second direction and a first direction, respectively.

The sidewall layer 44 is provided on the side surface at the Y-direction end of the electric conducting layer 43. As shown in FIG. 7, the sidewall layer 44 has a variable resistance layer 45. The sidewall layer 44 can also have a film other than the variable resistance layer 45 such as an electrode film. The variable resistance layer 45 functions as a variable resistance element VR. In the present example, the variable resistance layer 45 corresponds to, for example, a resistance-changing film.

The variable resistance layer 45 is provided between the electric conducting layer 43 and the side surfaces at the Y-direction ends of the electric conducting layers 42a to 42d.

The electric conducting layer 43 is made of, for example, polysilicon. The variable resistance layer 45 is made of, for example, a metal oxide. More specifically, the same material as that used in a cross-point memory cell can be used in the variable resistance layer 45. An electrode can be formed on the sidewall layer in addition to the variable resistance layer 45.

The resistive element film 20 is disposed between the corresponding semiconductor layer 35 and the bit line BL. The thickness of the resistive element film 20 is about 20 nm in the present example. In the present example, the resistive element film 20 corresponds to, for example, a resistive element layer.

The resistive element film 20 is configured by a resistive element film including a stack body in which insulating films 11 and metallic films 12 that are independent of each other are alternately and repetitively stacked in this order by the manufacturing method described above. Therefore, at least any one of the thickness and the nitrogen concentration of the insulating film 11 is adjusted for the linearity and the target resistance value. Thus, the resistive element film 20 functions as a current suppression element having the target resistivity without the deterioration of the linearity of the IV curve. As a result, according to the present embodiment, a ReRAM has appropriately effective resistance applicable at all voltages for the ReRAM operation and has considerably improved switching performance; for example, it is possible to reduce a switching voltage or a switching current.

When the stack body film 20 and the electric conducting layer 43 are in direct contact with each other, the film of the stack body film 20 in contact with the electric conducting layer 43 is preferably the metallic film 12. When the stack body film 20 and the N⁺-type semiconductor layer 35c are in direct contact with each other, the film of the stack body film 20 in contact with the N⁺-type semiconductor layer 35c is preferably the metallic film 12.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of a resistive element film, the method comprising:
sequentially repeating, two or more of times, a first film formation cycle to form an insulating film comprising a continuous layer by an ALD film formation method under a first condition, and a second film formation cycle to form a metal film comprising a continuous layer on the insulating film by the ALD film formation method under a second condition.

2. The method of claim 1,
wherein the thickness of the insulating film is adjusted within a range of 1 nm to 5 nm.

3. The method of claim 1,
wherein the thickness of the insulating film is adjusted within a range of 1.5 nm to 3 nm.

4. A resistance-changing memory device comprising:
a substrate;
first wiring line and second wiring line disposed on the substrate across each other;
a rectifier element disposed on the first wiring line via a first electrode at the intersection of the first and second wiring lines between the first and second wiring lines;
a resistive element film disposed on the rectifier element;
a storage element comprising a resistance-changing film on the resistive element film; and
a third electrode which is disposed on the storage element and which is electrically connected to the second wiring line,
wherein in the resistive element film, insulating films and a first film comprising a metal are alternately stacked between the first and second wiring lines.

5. The device of claim 4,
wherein the thickness of the insulating film is 1.5 nm to 3 nm.

6. The device of claim 4,
wherein the insulating film is silicon nitride (SIN) or aluminum nitride (AlN).

7. The device of claim 4,
wherein the insulating film is a nitride, and
the nitrogen concentration in the insulating film is adjusted to 1 to 60%.

8. The device of claim 4,
wherein the insulating film is SiₓN_{y}, and
0<y≦4, in which x=3.

9. The device of claim 4,
wherein the first film is selected from a tantalum nitride (TaN) film, a titanium nitride (TiN) film, a molybdenum nitride (MoN) film, a nickel nitride (NiN) film, a niobium nitride (NbN) film, and a vanadium nitride (VN) film.

10. The device of claim 4,
wherein the resistive element film is two or more insulating films, or two or more films comprising the metal.

11. The device of claim 4,
wherein the resistive element film is in direct contact with the rectifier element.

12. A resistance-changing memory device comprising:
a substrate;
a first layer extending in a first direction perpendicular to a main surface of the substrate;
second layers which extend in a second direction intersecting with the first direction and which are arranged in the first direction;
memory cells disposed between the first layer and the second layers;
a third electric conducting layer extending in a direction intersecting with the first and second directions;
a select element disposed on the third electric conducting layer; and
a resistive element layer disposed between the select element and the first electric conducting layer,
wherein the resistive element film comprises insulating films and first films with a metal that are alternately stacked in the first direction.

13. The device of claim 12,
wherein the thickness of the insulating film is 1.5 nm to 3 nm.

14. The device of claim 12,
wherein the insulating film is silicon nitride (SiN) or aluminum nitride (AlN).

15. The device of claim 12,
wherein the insulating film is a nitride, and
the nitrogen concentration in the insulating film is adjusted to 1 to 60%.

16. The device of claim 12,
wherein the insulating film is SiₓN_{y}, and
0<y≦4, in which x=3.

17. The device of claim 12,
wherein one of the first films is selected from a tantalum nitride (TaN) film, a titanium nitride (TiN) film, a molybdenum nitride (MoN) film, a nickel nitride (NiN) film, a niobium nitride (NbN) film, and a vanadium nitride (VN) film.
